(19) United States
(12) Patent Application Publication
(10) Pub. No.: US 2004/0244685 A1
(43) Pub. Date: Dec. 9, 2004

(54) Pretreated gas distribution plate

(75) Inventors: Anthony J. Ricci, Sunnyvale, CA (US); Babak Kadkhodayan, Oakland, CA (US)

Correspondence Address: BEYER WEAVER & THOMAS LLP, P.O. BOX 778, BERKELEY, CA, 94704-0778, US

(73) Assignee: Lam Research Corporation

(21) Appl. No.: 10/882,484

(22) Filed: Jun. 30, 2004

Related U.S. Application Data
(62) Division of application No. 09/408,921, filed on Sep. 30, 1999.

(51) Int. Cl. C23C 16/00

(52) U.S. Cl. 118/715

(57) ABSTRACT

A gas distribution plate (GDP) GDP is pretreated before implementation in a semiconductor fabrication apparatus so as to be stable over the operational lifetime of the GDP. The pre-treatment acts to reduce undesired reactions of the GDP with process chemistry used in the semiconductor fabrication apparatus. The pre-treatment is applied to at least a portion of the gas distribution plate. Preferably, surfaces of the gas distribution plate which come in contact with the process chemistry are pretreated.

### FIELD OF THE INVENTION

The present invention relates to the fabrication of semiconductor-based devices. More particularly, the present invention relates to gas distribution plates used in fabricating semiconductor-based devices.

### BACKGROUND OF THE INVENTION

In the fabrication of semiconductor-based devices, e.g., integrated circuits or flat panel displays, layers of materials may alternately be deposited onto and etched from a substrate surface. As is well known in the art, the etching of the deposited layers may be accomplished by a variety of techniques, including plasma-enhanced etching. In plasma-enhanced etching, the actual etching typically takes place inside a plasma processing chamber. To form the desired pattern on the substrate surface, an appropriate mask (e.g., photoresist) is typically provided. A plasma is then formed from a suitable etchant source gas, or mixture of gases, to etch areas that are unprotected by the mask, leaving behind the desired pattern.

To facilitate discussion, FIG. 1 illustrates a diagrammatic cross section of a plasma processing apparatus 100. The plasma processing apparatus 100 is suitable for fabrication of semiconductor based devices. The plasma processing apparatus 100 includes a plasma processing chamber 102 in which process parameters are tightly controlled to maintain consistent etch results for a wafer 104.

To control flow of gases into the plasma processing chamber 102, a gas distribution plate 106 is used. The gas distribution plate 106 includes holes 108 to pass process gases into the plasma processing chamber 102. A vacuum plate 112 maintains a sealed contact with the gas distribution plate 106 as well as with the top surface of the walls of the plasma processing chamber 102. Between the gas distribution plate 106 and the vacuum plate 112 are distribution channels 114. The distribution channels 114 distribute the process gases to the holes 108. A pump 110 is also included to draw the process gases and gaseous products from the plasma processing chamber 102 through a duct 111.

The gas distribution plate 106 is typically manufactured separately from the plasma processing apparatus 100. Upon implementation of a new gas distribution plate 106 within the plasma processing apparatus 100, particle defects in the wafer 104 appear. The particle defects compromise the fabrication quality of the wafer 104 and corresponding semiconductor products, and thus diminish wafer yield for the plasma processing apparatus 100. By way of example, a wafer yield of 30-50% is common for the plasma processing apparatus 100 as a result of particle defects upon initial implementation of a new gas distribution plate 106.

Typically, as the plasma processing apparatus 100 is run, the particle defects as a result of the new gas distribution plate 106 diminish and wafer yield increases. Thus, to combat the compromised wafer yield as a result of a new gas distribution plate 106, the plasma processing apparatus 100 is run until the particle defects substantially disappear. This ‘seasoning’ requires about ten RF hours, after which the gas distribution plate 106 may be used without compromising wafer yield.

Unfortunately, the gas distribution plate 106 is a consumable part. More specifically, the process chemistry used in the plasma processing chamber 102 erode the gas distribution plate 106. When the gas distribution plate 106 reaches a minimum thickness at any location, it must be replaced. Unfortunately, the replacement gas distribution plate introduces similar wafer yield defects. As a result, the plasma processing apparatus 100 must be run to season the replacement gas distribution plate until the particle defects substantially disappear. Unfortunately, this seasoning represents considerable downtime for the plasma processing apparatus 100 and cost for the semiconductor manufacturer. Undesirably, production is diminished and an entire manufacturing process may be interrupted. Further, this requirement seriously increases fabrication costs of semiconductor-based devices and represents an obstacle for plasma processing apparatus sales and maintenance.

In view of the foregoing, an improved gas distribution plate suitable for use in semiconductor manufacturing is required.

### SUMMARY OF THE INVENTION

In one aspect, the invention relates to a gas distribution plate (GDP) for use in a semiconductor fabrication apparatus, upon construction or as a replacement, without compromising semiconductor fabrication apparatus performance over the operational lifetime of the GDP. The GDP is pretreated before implementation in the semiconductor fabrication apparatus. The pre-treatment acts to minimize, and potentially eliminate, micro-defects which may react with process chemistry used in the semiconductor fabrication apparatus. The pre-treatment is applied to at least a portion of the gas distribution plate. Preferably, the surfaces of the gas distribution plate which come in contact with the process chemistry are pretreated by a thermal approach.

According to the present invention, particle defects produced from the reaction of the GDP and process chemistry used in the plasma processing chamber are substantially eliminated prior to implementation with a semiconductor fabrication apparatus. Advantageously, this eliminates the need for seasoning a new or replacement gas distribution plate, thereby improving tool availability. Broadly speaking, the GDP is suitable for application within any semiconductor manufacturing apparatus.

The invention relates in accordance with one embodiment to a semiconductor fabrication apparatus. The semiconductor fabrication apparatus includes a plasma processing chamber that receives process gases and forms a plasma therefrom. The semiconductor fabrication apparatus also includes a gas distribution plate including a plurality of holes that supply the process gases into the plasma processing chamber, a portion of the gas distribution plate being substantially non-reactive with the process chemistry used in the plasma processing chamber over the entire operating life of the gas distribution plate.

The invention relates in accordance with another embodiment to a method of making a gas distribution plate for use in a plasma processing apparatus. The method includes machining a material to form the gas distribution plate. The method also includes heating at least a portion of the gas distribution plate. The heating is directed to substantially eliminating micro-defects on at least the portion of the gas distribution plate.

The invention relates in accordance with yet another embodiment to a method of making a gas distribution plate for use in a plasma processing apparatus. The method includes grinding a material at a first level of material removal to shape the gas distribution plate. The method also includes drilling holes in the gas distribution plate. The method further includes grinding one or more surfaces of the gas distribution plate at a second level of material removal. The method additionally includes heating at least a portion of the gas distribution plate. The method may also include additional machining the gas distribution plate to maintain manufacturing tolerances.

### BRIEF DESCRIPTION OF THE DRAWINGS

The present invention is illustrated by way of example, and not by way of limitation, in the figures of the accompanying drawings in which like reference numerals refer to similar elements, and in which:

FIG. 1 illustrates a diagrammatic cross section of a plasma processing apparatus.

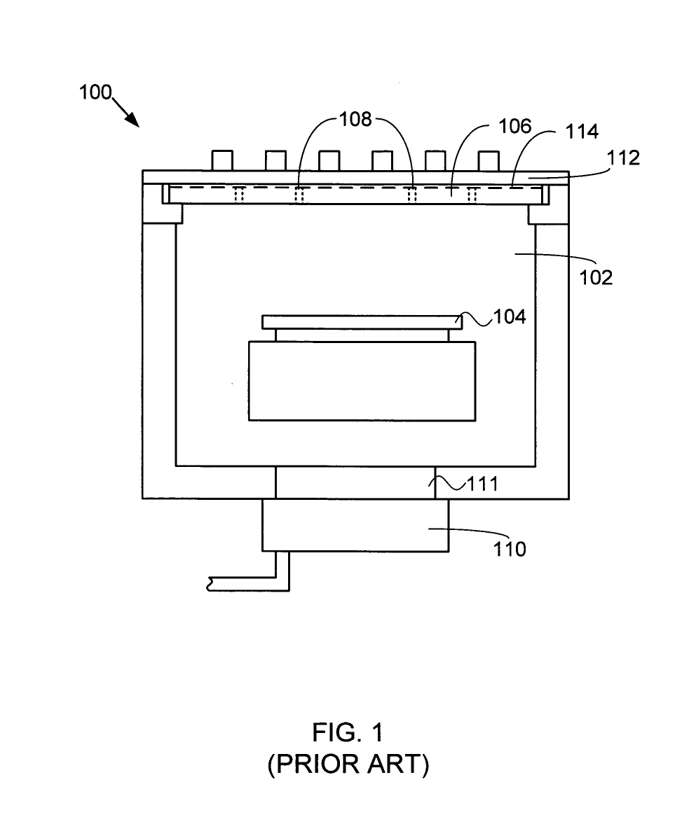

FIGS. 2A-2B illustrate a gas distribution plate in accordance with one embodiment of the present invention.

FIG. 3 is a flowchart representing the pretreatment of a gas distribution plate according to a preferred embodiment of the present invention.

### DETAILED DESCRIPTION OF THE INVENTION

In the following detailed description of the present invention, numerous specific embodiments are set forth in order to provide a thorough understanding of the invention. However, as will be apparent to those skilled in the art, the present invention may be practiced without these specific details or by using alternate elements or processes. In other instances well known processes, procedures, components, and circuits have not been described in detail so as not to unnecessarily obscure aspects of the present invention.

Conventionally, a gas distribution plate can be machined to shape prior to implementation with a plasma processing apparatus. Typically, the machining includes grinding (i.e., diamond wheel grinding) at several levels of material removal. In cases where the gas distribution plate includes ceramic portions, i.e. Si₃N₄, the extreme hardness of the ceramic material represents an obstacle to material removal. To overcome the extreme hardness of the ceramic material, the grinding includes high hardness additives, i.e. diamond particles. The high hardness additives leave surface damage on the gas distribution plate. On a microscopic level, the surface damage is seen as micro-defects, e.g., microcracks in the range of 50 microns.

While not wishing to be bound by theory, it has been found that the micro-defects react with process chemistry used within the semiconductor manufacturing apparatus. The by-products of this attack appear as particle defects on the wafer being manufactured. During use of the plasma processing apparatus and the gas distribution plate, the micro-defects in the surfaces of the gas distribution plate may suffer from chemical etching, ion bombardment or physical sputtering by the process gases and plasma used in the plasma processing chamber. As a result, the layer of surface damage and micro-defects erode, leaving a surface with less defects which suffers less attack. Eventually, as processes are run within the plasma processing chamber for an extended time, the micro-defects diminish to the extent that the production of particle defects no longer significantly compromises wafer yield.

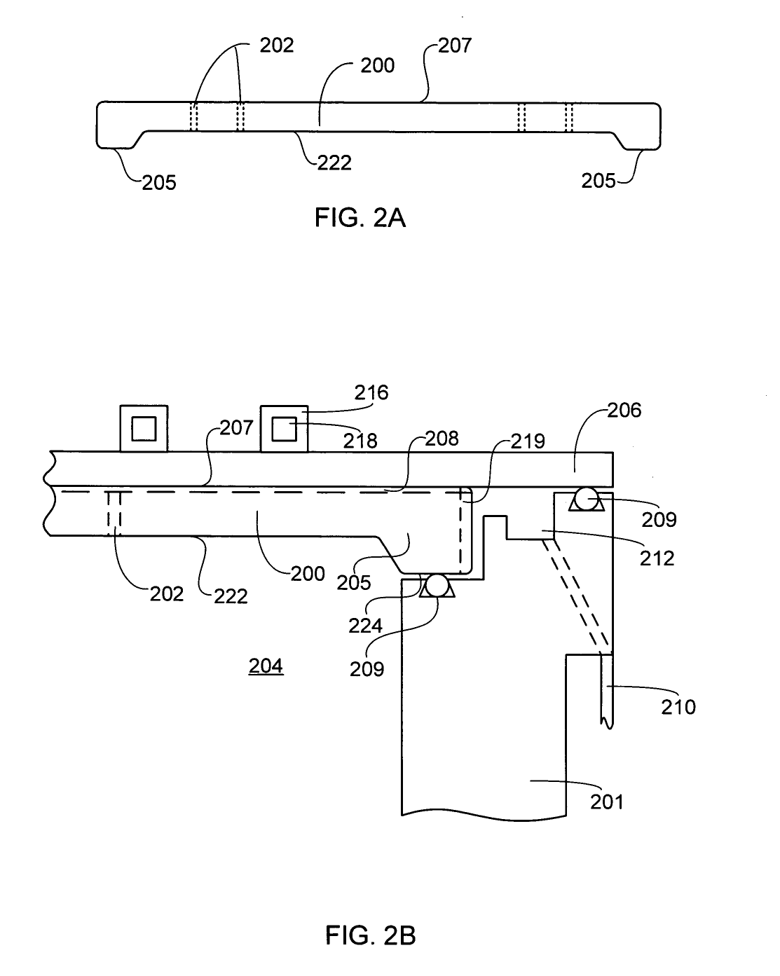

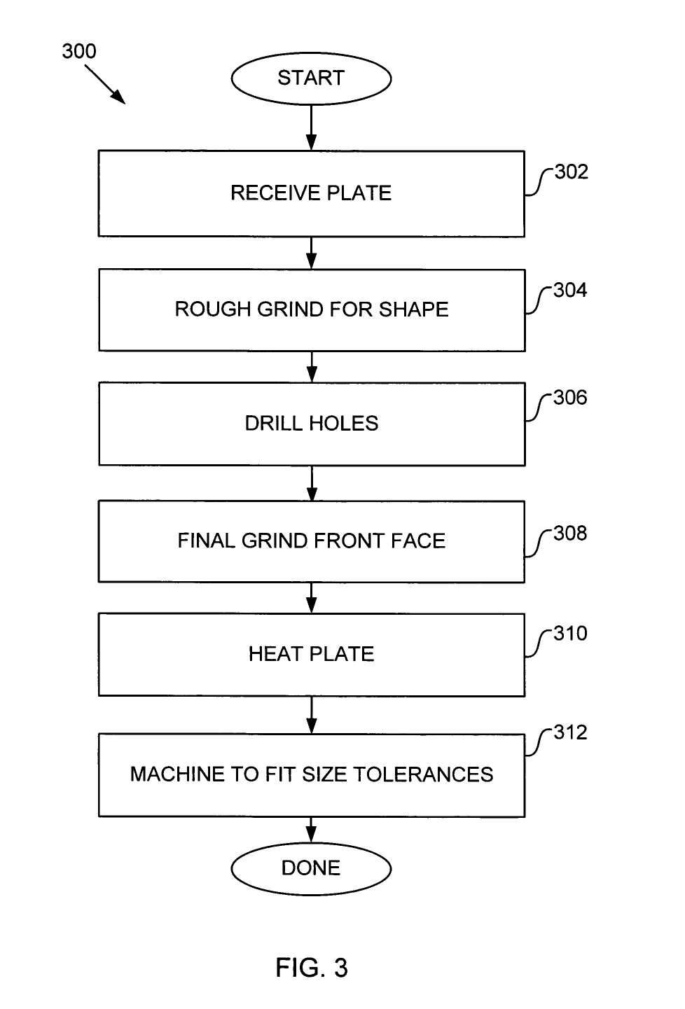

FIGS. 2A-2B illustrate a pretreated gas distribution plate (GDP) 200 in accordance with a preferred embodiment of the present invention. FIG. 2 is a cross-section view of the GDP 200, and FIG. 3 is a partial cross-section view of a plasma processing apparatus 201 having the GDP 200 installed therein. The GDP 200 is treated before implementation or installed within a plasma processing apparatus 201. The pretreatment acts to substantially prevent wafer-diminishing reactivity of the GDP 200 with the process chemistry used in the plasma processing apparatus 201 over the entire operational lifetime of the GDP 200. The process chemistry includes the process gases and plasma used in the plasma processing apparatus. In one embodiment, the pretreatment is directed to substantially reduce surface damage (e.g., micro-defects) caused by machining. Advantageously, the GDP 200 may be implemented with the plasma processing apparatus 201, upon initial construction or as a replacement, without compromising wafer yield for the plasma processing apparatus 201. In accordance with one embodiment of the invention, the pretreatment consists of heating the GDP 200. In another embodiment, the pretreatment can also be considered an annealing process in that it is subject to high temperatures to reduce surface damage.

Thus, the chemical and physical reactivity of the GDP 200 to process chemistry is substantially reduced, particularly during the initial hours of operational lifetime, as compared to conventional GDPs. In other words, the invention enables reliable and non-intrusive supply of process gases to a plasma pressure chamber to allow fabrication of modern semiconductor-based devices without compromise due to particle defects produced from the reaction of the GDP and process chemistry.

The GDP 200 is suitable for controlling the flow of process gases to a plasma processing chamber 204. The GDP 200 includes a plurality of holes 202 for permitting process gases to pass into the plasma processing chamber 204. The number and arrangement of the holes 202 may be varied as desired, i.e. for a particular goemetry of the plasma processing chamber 204.

A vacuum plate 206 seals the plasma processing chamber 204 along with O-rings 209 and a shoulder portion 205 of the GDP 200. In addition, the vacuum plate 206 maintains a sealed contact with a back face 207 of the GDP 200. To ensure this seal, the GDP 200 and the vacuum plate 206 are manufactured to predetermined tolerances. The vacuum plate 206 may have other functions, including for example, acting as a dielectric window. The vacuum plate 206 may also be cooled by a series of hollow conductors (coils) 216. The hollow conductors 216 include coolant 218 running through them to thermodynamically balance heat generated by the vacuum plate 206 acting as a dielectric window. The cooling of the vacuum plate 206 also serves to cool the GDP 200.

Between the GDP 200 and the vacuum plate 206 are distribution channels 208. The distribution channels 208 serve to distribute the process gases, supplied by a gas feed 210 and collected in a peripheral manifold 212, to the holes 202. In one embodiment, the distribution channels 208 are machined into the back face 207 of the GDP 200. As an example, the holes 202 may be arranged in a circular pattern. In one embodiment, the GDP 200 is a circular ceramic plate with the distribution channels 208 and the holes 202 arranged in a radial manner. More specifically, the GDP 200 in this embodiment has a diameter of 14 inches and is suitable for use with a Laurier 9100 as provided by Lam Research Corporation of Fremont, Calif.

The GDP 200 may be ion bombarded at a higher rate in areas proximate to power generation coils (e.g., coils 216), resulting in localized erosion of the GDP 200. Correspondingly, the GDP 200 may include locating notches 219. The locating notches 219 allow the GDP 200 to be repositioned (e.g., rotated with respect to the plasma processing chamber 204) to prevent excessive localized erosion as a result of localized high energy bombardment, thereby increasing the operational lifetime of the GDP 200. For example, for a circular GDP 200, the locating notches 219 may be positioned circumferentially such that the GDP 200 is repositioned by a simple rotation.

The GDP 200 may be made of any material which maintains a minimal sensitivity to process chemistry used in the plasma processing apparatus 201 over the operational lifetime of the GDP 200. In one embodiment, the material for the GDP 200 is selected such that the by-products of any chemical attack from process chemistry is gaseous and may thereby easily removed from the plasma processing chamber 204. In a preferred embodiment, the GDP 200 includes a ceramic material. By way of example, the entire GDP 200 may include a ceramic such as Si₃N₄, Al₂O₃, AlN and SiC. In this case, other materials may be alloyed into the ceramic to alter a particular material or performance property. In another embodiment, the GDP 200 may be a composite wherein a portion of the GDP 200 includes a ceramic. More specifically, a front face 222 of the GDP 200 which faces the plasma processing chamber 204, or any portion which is subject to contact with the plasma or process gases used in the plasma processing chamber 204, may include a ceramic.

Having briefly discussed the structure of the GDP 200 and a few relevant issues related to implementation with the plasma processing apparatus 201, the pretreatment of one or more portions of the GDP 200 will now be discussed.

In one embodiment, the GDP 200 is pretreated by exposing at least a portion of the GDP 200 to heat. The portion may be one or more surfaces of the GDP 200 which are exposed to the plasma used in the plasma processing chamber 204. Alternatively, the entire GDP 200 may be exposed to heat for a desired temperature and duration.

The heat administered during the pretreatment may vary considerably. Typically, the temperature and duration of the heat administered depends on a number of factors including, but not limited to, the GDP 200 material(s), GDP 200 size and geometry, the heating apparatus, the final grinding process used before heating, the number of GDPs run in the heating apparatus at a single time, material additives, temperature uniformity in the heating apparatus and temperature ramp time to desired temperature. By way of example, additives, such as MgO (or any other sintering aid), may affect the melting point of the ceramic and thereby affect the heating process.

The goal of the heating pretreatment may be flexibly defined. Preferably, the temperature and duration of heat application should be sufficient to substantially eliminate micro-defects on the concerned portion of the GDP 200. In one embodiment, the heating may proceed until a smoothness tolerance for the concerned portion or portions is obtained. Alternatively, the heating may proceed until the GDP 200 produces a particular level of particle defects upon initial implementation within the plasma processing chamber 201. By way of example, heating may be directed to achieve a defect density of less than 0.1 particle defects per square centimeter upon initial implementation within the plasma processing chamber 201.

The present invention is not limited to any particular heating methodology. In one embodiment, the heating may be performed by exposing the concerned portions to a single temperature for a predetermined duration. Alternatively, the temperature within the heating apparatus may be incrementally increased as heating progresses, or modified in any other suitable fashion, to reach the desired pretreatment goal for the GDP 200, or portions thereof. In yet another embodiment, heating may be such that the GDP 200 maintains machining specifications, i.e. a flatness specification. Preferably, heating is performed at the minimum temperature required to obtain the pretreatment goals so as to minimize any potential for GDP 200 warping. In one embodiment, the GDP 200 is heated isothermally. In other words, as heating progresses, temperature variation across the part is minimized. The heating methodology may also include cool down sensitive to the GDP 200. More specifically, the cooling of the GDP 200 may be performed in such a manner as to minimize introduction of defects and warpage as a result of the cooling.

In some cases, the heating may lead to warping of the GDP 200. If the warping results in the dimensions of the GDP 200 falling outside of assembly and manufacturing tolerances, a portion or portions of the GDP 200 may be machined subsequent to heating. For example, the back face 207 of the GDP 200 typically has a flatness tolerance to maintain tight contact with the vacuum plate 206. Correspondingly, the back face 207 may be machined, i.e., ground, to maintain the flatness tolerance after heating.

The heating of the concerned portions of the GDP 200 may be performed in any suitable apparatus. In one embodiment, a gas furnace is used. Preferably, the heating is performed in an inert environment (i.e., oxygen free). By way of example, a in-house furnace as provided by Cercom of Vista, Calif. is suitable. Alternatively, the pre-treatment of the GDP 200 may performed using a flame-polishing.

In a particular embodiment, a fourteen inch circular, ceramic GDP 200 comprising Si₃N₄ may be heated within an oven at a temperature ranging from 1500 to 1600 degrees Centigrade for a duration of 5 to 10 hours. In a specific embodiment, the same structure may be ramped from 300 degrees Centigrade and heated at a steady temperature of 1500 degrees Centigrade for 5-10 hours in a graphite furnace. In another specific embodiment, the same structure may be ramped from 300 degrees Centigrade and heated at a steady temperature of 1600 degrees Centigrade for 5-8 hours in a graphite furnace. In yet another specific embodiment, the same structure may be ramped from 900 degrees Centigrade and heated at a steady temperature of 1500 degrees Centigrade for a duration of 5-8 hours in a Si₃N₄ furnace. Subsequently, the GDP 200 may be implemented within the plasma processing chamber 201, such as that included within a Lam 9100 Dielectric Etcher by Lam Research Corporation of Fremont, Calif., to produce particle defects less than 0.1 particle defects per square centimeter.

Having discussed a preferred method of pretreating the GDP 200 to substantially eliminate micro-defects which may lead to particle defects in a wafer upon implementation, other methods of pretreating will now be briefly discussed.

In one embodiment, a portion of the GDP 200 may be pretreated by lapping. In this case, the GDP 200 is rubbed with a pad and slurry to substantially eliminate micro-defects. This method is particularly well suited for a geometrically simple GDP 200, i.e. when the GDP 200 does not have the shoulder portion 205 or any other corners which may impede a lapping pad. Typically, the lapping is performed using progressively smaller slurry particle sizes to incrementally reduce any damage which may be caused by the lapping process. In another embodiment, the GDP 200, or a portion thereof, may be pretreated by imparting ultrasonic energy. Alternatively, the GDP 200, or a portion thereof, may be pretreated by chemical etching. In all these cases, the pretreatment method may be sensitive to GDP 200 based on size, material additives, etc.

The pretreatment of the GDP 200 according to a specific embodiment of the invention will now be described with reference to flowchart 300 of FIG. 3. Pretreatment according to flowchart 300 subjects a machined GDP 200 to heat. Initially, the GDP 200 to be pretreated is received (step 302). In the case where the GDP 200 is a composite comprising more than one material, the flowchart 300 may include assembly of the previously separate pieces. Areas of the GDP 200 are then ground in one or more grinding applications (304). For example, the GDP 200 may be ground to shape to include the shoulder portions 205. The grinding may include multiple grinding applications at differing levels of material removal. Alternatively, the grinding may include separate grinding of the front face 222 and back face 207 of the GDP 200.

The flowchart 300 proceeds with drilling the holes 202 in the GDP 200 (306). In addition, the holes may be reamed or otherwise suitably altered to establish mechanical tolerances. Subsequently, one or more portions of the GDP 200, such as the front face 222, may be ground again to minimize micro-defects. The GDP 200 is then placed within a furnace, or other suitable heating apparatus, which is capable of heating the GDP 200 (310). Once placed within the heating apparatus, the GDP 200 is pretreated by heating one or more exposed portions of the GDP 200. The heating parameters may be varied as described above and as one skilled in the art will appreciate.

After heating is completed and the GDP 200 is removed from the heating apparatus, the flowchart 300 may include machining the GDP 200 to re-establish any tolerances lost as a result of warping and/or thermal expansion during the heating (312). The present invention also includes any other steps used to facilitate implementation in the plasma processing apparatus 201. By way of example, a contact surface 224 of the shoulder portion 205 used in sealing the plasma processing chamber 201 may be further smoothed. After pretreatment is finished, the GDP 200 may then be assembled into the plasma processing apparatus 201.

Advantageously, according to the present invention, particle defects produced from the reaction of micro-defects in the GDP 200 and process chemistry used in the plasma process chamber are substantially eliminated during the operational lifetime of the GDP. The GDP 200 is suitable for application within any semiconductor manufacturing apparatus. By way of example, the present invention is suitable for application with a dielectric etch reactor.

Although the present invention has addressed specifically pre-treating the GDP 200, the present invention is also applicable to pre-treat other portions of a plasma processing apparatus which may compromise wafer yield as a result of reaction with process chemistry. More specifically, gas injection into the plasma-processing chamber may be introduced in a variety of ways besides through a GDP. By way of example, gas injection may be introduced through injection ports in the side walls of the plasma processing chamber. Thus, the pre-treatment methods of the present invention are suitable to prevent the formation of particle defects from any gas injection device and is not necessarily limited to a GDP. Alternatively, other parts of the plasma processing chamber walls may also be exposed to plasma and thus cause particle defects. Examples of these other parts include the inner surfaces of plasma processing chamber or barrier walls used in the vicinity of a wafer which may include material such as ceramic capable of compromising yield if not pre-treated. Correspondingly, the pre-treatment methods of the present invention are suitable for any surface or structure of a plasma processing apparatus which may compromise wafer production as a result of reaction with process chemistry. Broadly speaking, the pre-treatment methods of the present invention are suitable for any surface or structure of a plasma processing apparatus which may benefit as a result of the pre-treatment.

Although only a few embodiments of the present invention have been described in detail, it should be understood that the present invention may be embodied in many other specific forms without departing from the spirit or scope of the invention. Particularly, although the invention has been described primarily in the context of a circular GDP 200 having shoulders 205, the present invention is not limited to any particular geometry. Therefore, the present examples are to be considered as illustrative and not restrictive, and the invention is not to be limited to the details given herein, but may be modified within the scope of the appended claims.

1-18. (Canceled).

19. A method of making a gas distribution plate for use in a plasma processing apparatus, said method comprising:
machining a material to form the gas distribution plate; and
subsequently annealing at least a portion of the gas distribution plate, reducing damage caused by machining the material.

20. A method as recited in claim 19 wherein the material includes a ceramic.

21. A method as recited in claim 20 wherein the material includes at least one of Si₃N₄ and SiC.

22. A method as recited in claim 21 wherein said annealing occurs at a controlled temperature for a prolonged time.

23. A method as recited in claim 22 wherein the controlled temperature is between about 1500 degrees Celsius to 1600 degrees Celsius.

24. A method as recited in claim 22 wherein the prolonged time is from about 5 to 10 hours.

25. A method as recited in claim 24 wherein the controlled temperature is between about 1500 degrees Celsius to 1600 degrees Celsius.

26. A method as recited in claim 19 wherein said machining includes grinding the material.

27. A method as recited in claim 25 wherein machining includes drilling holes in the material.

28. A method as recited in claim 19 wherein said method further
includes: refinishing at least a section of the gas distribution plate following said annealing.

29. A method of making a gas distribution plate for use in a plasma processing apparatus, the method comprising:
grinding a material at a first stage of material removal to shape the gas distribution plate;
drilling holes in the gas distribution plate to facilitate gas distribution during use;
grinding one or more surfaces of the gas distribution plate at a second stage of material removal; and
subsequently annealing at least a portion of the gas distribution plate.

30. A method as recited in claim 29 wherein the material is a composite.

31. A method as recited in claim 29 wherein the method further comprises: machining the gas distribution plate after annealing to fit one or more tolerances.

32. A method as recited in claim 29 wherein the portion of the gas distribution plate is rendered substantially non-reactive by smoothing the portion before implementation within the semiconductor fabrication apparatus.

33. A method as recited in claim 29,
wherein the grinding during the first stage is course grinding, and
wherein the grinding during the second stage is fine grinding.

34. A method as recited in claim 29 wherein grinding at a first stage includes forming a contour.

35. A method of improving the performance of a gas distribution plate for use in a semiconductor fabrication apparatus, the method comprising annealing at least a portion of the gas distribution plate before placing the gas distribution plate in the semiconductor fabrication apparatus, wherein the annealing reduces the reactivity of the gas distribution plate with process chemistry used in the semiconductor fabrication apparatus.

36. A method as recited in claim 35 wherein the annealing includes heating at least the portion of the gas distribution plate.

37. A method as recited in claim 35 wherein the annealing serves to smooth at least a surface of the gas distribution plate exposed to a plasma processing chamber included in the semiconductor fabrication apparatus.

38. A method, as recited in claim 27, wherein the annealing is performed before the gas distribution plate is placed in a plasma processing apparatus and wherein the annealing removes micro defects created by the machining.

39. A method, as recited in claim 19, wherein the annealing is performed before the gas distribution plate is placed in a plasma processing apparatus.

40. A method as recited in claim 19 wherein said annealing occurs at a controlled temperature for a prolonged time.

41. A method as recited in claim 40 wherein the controlled temperature is between about 1500 degrees Celsius to 1600 degrees Celsius.

42. A method as recited in claim 40 wherein the prolonged time is from about 5 to 10 hours.

43. A method as recited in claim 42 wherein the controlled temperature is between about 1500 degrees Celsius to 1600 degrees Celsius.

44. A method as recited in claim 19 wherein machining includes drilling holes in the material.

45. A method as recited in claim 29 wherein the material includes a ceramic.

46. A method as recited in claim 29 wherein the material includes at least one of Si₃N₄ and SiC.

47. A method as recited in claim 46 wherein said annealing occurs at a controlled temperature for a prolonged time.

48. A method as recited in claim 47 wherein the controlled temperature is between about 1500 degrees Celsius to 1600 degrees Celsius.

49. A method as recited in claim 47 wherein the prolonged time is from about 5 to 10 hours.

50. A method as recited in claim 49 wherein the controlled temperature is between about 1500 degrees Celsius to 1600 degrees Celsius.

51. The method, as recited in claim 50, wherein the annealing is performed before the gas distribution plate is placed in a plasma processing apparatus and substantially eliminates micro-defects.

52. The method, as recited in claim 29, wherein the annealing is performed before the gas distribution plate is placed in a plasma processing apparatus.

53. A method as recited in claim 35 wherein the material includes a ceramic.

53. A method as recited in claim 35 wherein the material includes at least one of Si₃N₄ and SiC.

54. A method as recited in claim 53 wherein said annealing occurs at a controlled temperature for a prolonged time.

55. A method as recited in claim 54 wherein the controlled temperature is between about 1500 degrees Celsius to 1600 degrees Celsius.

56. A method as recited in claim 54 wherein the prolonged time is from about 5 to 10 hours.

57. A method as recited in claim 56 wherein the controlled temperature is between about 1500 degrees Celsius to 1600 degrees Celsius.
